(19) United States
(12) Patent Application Publication
(10) Pub. No.: US 2019/0363206 A1
(43) Pub. Date: Nov. 28, 2019

(54) SEMICONDUCTOR DEVICE

(71) Applicant: RIKEN, Saitama (JP)

(72) Inventors: Kenjiro FUKUDA, Saitama (JP); Takao SOMEYA, Saitama (JP)

(21) Appl. No.: 16/529,719

(22) Filed: Aug. 1, 2019

Related U.S. Application Data
(63) Continuation of application No. PCT/JP2018/003475, filed on Feb. 1, 2018.

(30) Foreign Application Priority Data
Feb. 3, 2017 (JP) 2017-019126

(51) Int. Cl. H01L 31/0445; H01L 31/18; H01L 31/0224

(52) U.S. Cl. CPC H01L 31/0445; H01L 31/182; H01L 31/0224; H01L 31/1884

(57) ABSTRACT

Provided is a semiconductor device including a first base material layer that is elastic; a first electrode layer provided on the first base material layer; a semiconductor layer provided on the first electrode layer; a second electrode layer provided on the semiconductor layer; and a second base material layer that is elastic and provided on the second electrode layer, wherein a neutral plane is positioned between a center of the first electrode layer and a center of the second electrode layer in the thickness direction, n indicates the number of layers in the semiconductor device, Eᵢ indicates an elastic modulus of an i-th layer from the one surface of the semiconductor device, among the layers of the semiconductor device, and tᵢ and tⱼ respectively indicate thicknesses of the i-th layer and a j-th layer.

### CROSS REFERENCE TO RELATED APPLICATION

The contents of the following Japanese patent application and international application are incorporated herein by reference:

Japanese Patent Application No. 2017-019126 filed on Feb. 3, 2017 and International Application No. PCT/JP2018/003475 filed on Feb. 1, 2018.

### BACKGROUND

### 1. Technical Field

The present invention relates to a semiconductor device.

### 2. Related Art

A flexible electronic circuit is known that includes an organic transistor, which is experimentally produced using an ultrathin (1 μm) polymer foil as the substrate, as shown in Non-Patent Document 1, for example.
Non-Patent Document 1: Martin Kaltenbrunner, Tsuyoshi Sekitani, Jonathan Reeder, Tomoyuki Yokota, Kazunori Kurihara, Takeyoshi Tokuhara, Michael Drack, Reinhard Schwodiauer, Ingrid Graz, Simona Bauer-Gogonea, Siegfried Bauer, Takao Someya, “An ultra-lightweight design for imperceptible plastic electronics”, Nature, 499, (7459), 458-463, 2013.

A flexible sheet device is proposed in which flexible sensors, power generating elements, light emitting elements, secondary batteries, and the like are combined with such a flexible electronic substrate. This type of sheet device utilizes its lightweight and flexible features to realize a wearable device worn directly on clothing or the surface of a body, to monitor health indicators such as body temperature, pulse, body hydration rate, blood pressure, and the like of human or animal and to transmit or record this data, and focus has been placed on attempts to use such a device to help with healthcare. There is a desire for a wearable device to follow along with the movement of a person or animal, and to be usable over a certain period without experiencing a decline in performance while enduring bending when attached or detached.

There is a desire for a semiconductor device to have a laminated structure that is resistant to damage and performance deterioration when subjected to bending deformation. In a semiconductor device that includes two electrode layers and a semiconductor layer provided between these electrode layers, when there is a large difference in the distortion applied to the two electrode layers at the time when the semiconductor device is deformed, the one electrode layer that experiences greater distortion is much more likely than the other electrode layer to break.

### BRIEF DESCRIPTION OF THE DRAWINGS

FIG. 1 schematically shows an example of a cross section of a solar cell device 100 according to one embodiment.

FIG. 2 is a cross-sectional diagram for describing the distortion occurring in the solar cell device 100.

FIG. 3 shows the dependency of a on t₁, in a case where R=1 (μm).

FIG. 4 shows the upper limit value and lower limit value of (E₇/E₁)×(t₇/t₁)² in a case where t₁=500 (μm) and E₁=0.01 (GPa), with t₇/t₁ as a parameter.

FIG. 5 shows the upper limit value and lower limit value of (E₇/E₁)×(t₇/t₁)² in a case where t₁=100 (μm) and E₁=0.01 (GPa), with t₇/t₁ as a parameter.

FIG. 6 shows the upper limit value and lower limit value of (E₇/E₁)×(t₇/t₁)² in a case where t₁=50 (μm) and E₁=0.01 (GPa), with t₇/t₁ as a parameter.

FIG. 7 shows the upper limit value and lower limit value of (E₇/E₁)×(t₇/t₁)² in a case where t₁=10 (μm) and E₁=0.01 (GPa), with t₇/t₁ as a parameter.

FIG. 8 shows the upper limit value and lower limit value of (E₇/E₁)×(t₇/t₁)² in a case where t₁=100 (μm) and E₁=1 (GPa), with t₇/t₁ as a parameter.

FIG. 9 shows the upper limit value and lower limit value of (E₇/E₁)×(t₇/t₁)² in a case where t₁=100 (μm) and E₁=0.001 (GPa), with t₇/t₁ as a parameter.

### DESCRIPTION OF EXEMPLARY EMBODIMENTS

Hereinafter, some embodiments of the present invention will be described. The embodiments do not limit the invention according to the claims, and all the combinations of the features described in the embodiments are not necessarily essential to means provided by aspects of the invention.

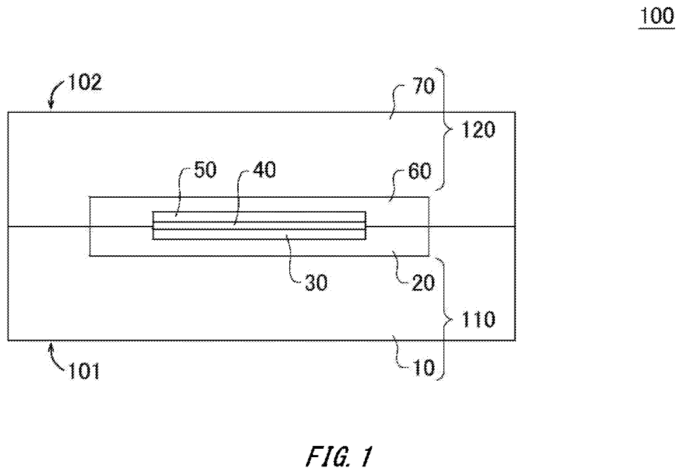

FIG. 1 schematically shows an example of a cross section of a solar cell device 100 according to one embodiment. The solar cell device 100 is an example of a semiconductor device.

The solar cell device 100 includes a first base material layer 110, a first electrode layer 30, a photoelectric conversion layer 40, a second electrode layer 50, and a second base material layer 120. The first electrode layer 30 is provided on the first base material layer 110. The second base material layer 120 is provided on the second electrode layer 50. The first base material layer 110 includes a first elastic layer 10 and a first film layer 20. The second base material layer 120 includes a second film layer 60 and a second elastic layer 70.

The first base material layer 110 and the second base material layer 120 are elastic. The first base material layer 110 is transparent. The second base material layer 120 does not need to be transparent, but may be transparent.

In the solar cell device 100, the first elastic layer 10 provides a first surface 101 of the solar cell device 100, and the second elastic layer 70 provides a second surface 102 of the solar cell device 100. The first surface 101 is an incident surface through which light enters the solar cell device 100. The layers of the solar cell device 100 are provided in the order of the first elastic layer 10, the first film layer 20, the first electrode layer 30, the photoelectric conversion layer 40, the second electrode layer 50, the second film layer 60, and the second elastic layer 70, from the first surface 101.

The first elastic layer 10 is transparent. The first elastic layer 10 is formed of an elastic material. The first elastic layer 10 may be a rubber layer formed of a rubber material such as acrylic rubber, silicone rubber, butadiene rubber, styrene butadiene rubber, isoprene rubber, chloroprene rubber, nitrile rubber, ethylene propylene rubber, or urethane rubber. Alternatively, the first elastic layer 10 may be formed of a soft fluorine resin material such as ETFE or PVF. As another alternative, the first elastic layer 10 may be formed by a polyolefin such as polyethylene, polypropylene, polyvinyl chloride, polyvinylidene chloride, or polyvinyl alcohol; a soft polyolefin copolymer such as EVA or EMA; polystyrene, AS resin, ABS resin, or foams thereof; or cured resins such as condensation-polymerized resins such as polycarbonate, polyamide, or polyester, phenol resin, melamine resin, urea resin, epoxy resin, acrylic resin, methacrylic resin, or unsaturated polyester resin.

If the semiconductor device has a solar power generation function or light emission function, the average value for the total light transmittance of the first elastic layer 10 in the visible light band is preferably greater than or equal to 60%, more preferably greater than or equal to 70%. The first elastic layer 10 may cause scattering, as long as the average value for the total light transmittance is within these ranges.

The first film layer 20 is provided on the first elastic layer 10. The first film layer 20 is transparent. The first film layer 20 is formed of a resin material. Specifically, the first film layer 20 may be formed of a xylylene-based polymer material such as parylene; an epoxy resin material such as SU-8; a polyester-based material such as polyethylene terephthalate or polyethylene naphthalate; a cyclopolyolefin material; a polycarbonate material; a methacrylic resin material; a polyimide material; or various photoresist materials. Among these materials, in consideration of transparency, heat resistance, surface smoothness, and the like, a photocurable or thermosetting resin material or a transparent polyimide material is suitably used. Alternatively, the first film layer 20 may be formed by an flexible glass substrate with a thickness less than or equal to 50 μm, preferably less than or equal to 30 μm, and most preferably less than or equal to 10 μm. A flexible glass substrate provided with a resin coating that smooths micro cracks on both surfaces thereof to prevent breakage is suitably used here. The first film layer 20 may be used as a base material for forming the first electrode layer 30 when manufacturing the solar cell device 100.

The first electrode layer 30 is provided on the first film layer 20. The first electrode layer 30 is transparent. Specifically, the first electrode layer 30 is transparent to visible light. The average value for the total light transmittance of the first electrode layer 30 in the visible light band is preferably greater than or equal to 60%, more preferably greater than or equal to 70%. The first electrode layer 30 may cause scattering, as long as the total light transmittance is within these ranges. The first electrode layer 30 is a transparent electrode layer, for example. The first electrode layer 30 may be formed of a metal oxide or the like, such as indium tin oxide (ITO), nickel oxide, tin oxide, indium oxide, indium-zirconium oxide (IZO), titanium oxide, or zinc oxide. Alternatively, the first electrode layer 30 may be formed as a thin film of aluminum or silver to be transparent, an organic conductive material that is transparent such as PEDOT:PSS, a combination of these materials, or may be combined with an auxiliary electrode consisting and lines of aluminum, gold, silver, copper, or the like.

The first electrode layer 30 may be a metal mesh layer in which metal having a mesh structure serving as an electrode is held by a transparent material. This mesh structure may be formed of silver, gold, copper, or the like. The first electrode layer 30 may be a metal nanowire layer in which metal nanowires serving as an electrode are held by a transparent material. If a metal mesh layer or metal nanowire layer is used as the first electrode layer 30, the electrode portion does not need to be transparent, and the entire first electrode layer 30 may be made transparent by having the portion formed of the transparent material transparently passing light. The first electrode layer 30 may be formed of a conductive polymer.

The photoelectric conversion layer 40 is provided on the first electrode layer 30. The photoelectric conversion layer 40 includes a plurality of photoelectric converting elements. Specifically, the photoelectric conversion layer 40 may be a layer formed of thin film monocrystalline silicon, thin film polycrystalline silicon, thin film microcrystalline silicon, amorphous silicon, a perovskite type compound, other inorganic semiconductor materials, or dye materials. Alternatively, the photoelectric conversion layer 40 may be a layer formed of an organic semiconductor material. The organic semiconductor material may be a mixed layer in which an n-type organic semiconductor and a p-type organic semiconductor have a bulk heterojunction. Examples of the n-type organic semiconductor includes fullerenes, fullerene derivatives, a carbon material such as carbon nanotubes, various condensed aromatic hydrocarbons, perylene, cyanoquinodimethane, oxadiazole derivatives such as PBD, styrylanthracene derivatives such as BSA-1, bathocuproine, a benzoquinolinol beryllium complex, a benzothiazole zinc complex, and the like. Examples of the p-type organic semiconductor include condensed aromatic hydrocarbons such as pentacene, rubrene or thiophene, porphyrin, phthalocyanine, diamine derivatives, amine derivatives such as TPD, and the like. The photoelectric conversion layer 40 is an example of a semiconductor layer. A hole transport layer, hole injection layer, electron transport layer, electron blocking layer, or the like may be interposed between the photoelectric conversion layer 40 and the first electrode layer 30 and second electrode layer 50 as needed, in order to improve efficiency, prevent shorts, or the like.

The second electrode layer 50 is provided on the photoelectric conversion layer 40. The second electrode layer 50 is a back electrode layer in the solar cell device 100. For example, the second electrode layer 50 is a metal film made of gold, silver, aluminum, or the like. The second electrode layer 50 does not need to be transparent.

The second film layer 60 is provided on the second electrode layer 50. The second film layer 60 may be formed of materials provided as the examples of materials forming the first film layer 20 in paragraph 0025. The material forming the second film layer 60 may be the same as or different from the material forming the first film layer 20. In the present embodiment, the second film layer 60 and the first film layer 20 are formed of parylene. The second film layer 60 may function as a sealing material for sealing the first electrode layer 30, the photoelectric conversion layer 40, and the second electrode layer 50. Alternatively, the second film layer 60 may be formed by photocurable or thermosetting resin such as epoxy resin, acrylic resin, or methacrylic resin. The thickness of the second film layer 60 is preferably equivalent to or less than or equal to the thickness of the first film layer 20, in consideration of flexibility and handling ability during manufacturing of the device.

The second elastic layer 70 is provided on the second film layer 60. The second elastic layer 70 may be formed of the same material as the first elastic layer 10. Specifically, the second elastic layer 70 is an elastic layer formed of a rubber material such as acrylic rubber. The second elastic layer 70 may be a rubber layer formed of a rubber material such as silicone rubber, butadiene rubber, styrene butadiene rubber, isoprene rubber, chloroprene rubber, nitrile rubber, ethylene propylene rubber, or urethane rubber. Alternatively, the second elastic layer 70 may be formed of a soft fluorine resin material such as ETFE or PVF. As another alternative, the first elastic layer 10 may be formed by a polyolefin such as polyethylene, polypropylene, polyvinyl chloride, polyvinylidene chloride, or polyvinyl alcohol; a soft polyolefin copolymer such as EVA or EMA; polystyrene, AS resin, ABS resin, or foams thereof; or cured resins such as condensation-polymerized resins such as polycarbonate, polyamide, or polyester, phenol resin, melamine resin, urea resin, epoxy resin, acrylic resin, methacrylic resin, or unsaturated polyester resin. Granular or fibrous fillers may be dispersed in these materials in consideration of strength and function demands. The filler material can be silica, carbon, carbon nanotubes, glass, cellulose nanofiber, or the like. Alternatively, embossing, an uneven coating, or the like may be applied to the surface of the second elastic rubber layer, in consideration of preventing regular reflection, preventing adhesion, and design.

In this way, the solar cell device 100 has a laminated semiconductor element structure in which the photoelectric conversion layer 40 is provided between the first electrode layer 30 and the second electrode layer 50. As described further below, the solar cell device 100 has a structure in which the laminated semiconductor element is sandwiched between the first base material layer 110 and the second base material layer 120, such that a neutral plane of the solar cell device 100 is positioned between the first elastic layer 10 and the first film layer 20. Therefore, when distortion is applied to the first electrode layer 30 during deformation of the solar cell device 100, it is possible to reduce the difference between this distortion and the distortion applied to the second electrode layer 50. Therefore, it is possible to prevent the distortion applied to one of the electrode layers from becoming significantly larger than the distortion applied to the other electrode layer. Accordingly, it is possible to improve the distortion endurance of the solar cell device 100.

As one usage embodiment, the solar cell device 100 is provided on a deformable material. This material can be clothing, a rubber material, or the like, for example. Alternatively, the material can be directly attached to the skin of a person or animal, and combined with a sensor and independent power source realized by a solar cell to monitor blood pressure, temperature, humidity, or the like. Since the solar cell device 100 can be adapted to many uses and materials, the solar cell device 100 must have an extremely high capability for deformation such as expanding/contracting and bending. If the solar cell device 100 can endure bending deformation, the solar cell device 100 can also be designed to endure expansion/contraction caused by stretching or further bending as a folding device in which the front and back are alternately bent and folded. If the curvature radius of the bending portion can be set to be small, the solar cell device 100 has a corresponding bending endurance and the degree of freedom for the shape of the folding is increased, thereby improving the practicality. The following describes characteristics to be included in each layer of the solar cell device 100 according to one embodiment, with one goal set to be making the solar cell device 100 able to endure bending with a curvature radius of 1 μm.

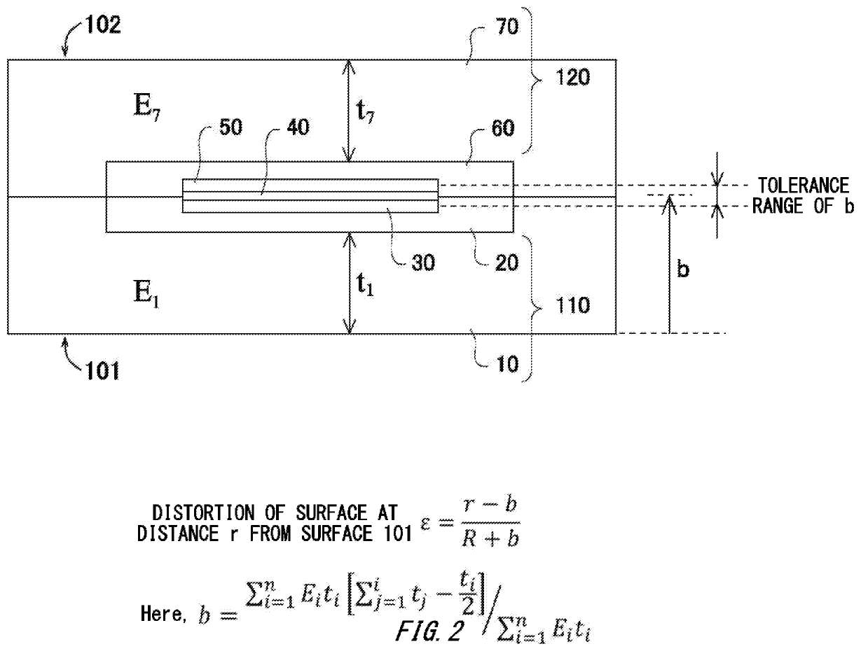

FIG. 2 is a cross-sectional diagram for describing the distortion occurring in the solar cell device 100. The solar cell device 100 includes seven layers. In the present embodiment, the elastic modulus E and thickness t of each layer of the solar cell device 100 are represented using natural numbers i as subscript for identifying each layer. Specifically, in the solar cell device 100, with the first elastic layer 10 that is the layer on the first surface 101 side being a first layer, the elastic modulus of the i-th layer counting from the first elastic layer 10 is represented as Eᵢ. Furthermore, the thickness of the i-th layer counting from the first elastic layer 10 is represented as tᵢ. When identifying the thickness of a layer independently from i, j is used as a natural number to represent the thickness of the j-th layer counting from the first elastic layer 10 as tⱼ. The elastic modulus in the present embodiment is the longitudinal elastic modulus. The elastic modulus in the present embodiment may be the longitudinal elastic modulus measured using a bending test.

In the solar cell device 100, the distortion a of a surface at a distance r from the first surface 101 is represented as shown in the expression below.

$$ɛ = \frac{r - b}{R + b} \qquad Expression 1$$

Here, R is the curvature radius of the solar cell device 100, and b represents the distance from the first surface 101 to the neutral plane and is represented by the expression below.

$$b = {\sum }_{i = 1}^{n} {E}_{i} {t}_{i} [ {\sum }_{j = 1}^{i} {t}_{j} - \frac{{t}_{i}}{2} ] / {\sum }_{i = 1}^{n} {E}_{i} {t}_{i} \qquad Expression 2$$

Here, n indicates the number of layers in the solar cell device 100. As described above, Eᵢ indicates the elastic modulus of the i-th layer from the first surface 101, and tᵢ and tⱼ respectively indicate the thickness of the i-th layer and the j-th layer.

In the solar cell device 100, the neutral plane is positioned between the center of the first electrode layer 30 and the center of the second electrode layer 50 in the thickness direction. Specifically, the thickness t₁ and elastic modulus E₁ of the first elastic layer 10 and the thickness t₇ and elastic modulus E₇ of the second elastic layer 70 are set such that the neutral plane is positioned between the center of the first electrode layer 30 and the center of the second electrode layer 50 in the thickness direction.

Table 1 shows parameters used in embodiment examples of the solar cell device 100 described further below. Each embodiment example is characterized by the thickness t₁ and elastic modulus E₁ and the thickness t₇ and elastic modulus E₇.

TABLE 1

| LAYER | t (μm) | E (Gpa) |
|---|---|---|
| 7 | t₇ | E₇ |
| 6 | 1.0 | 4 |
| 5 | 0.1 | 83 |
| 4 | 0.3 | 1 |
| 3 | 0.1 | 116 |
| 2 | 1.0 | 4 |
| 1 | t₁ | E₁ |

In each embodiment example, the first film layer 20 and the second film layer 60 may be formed of parylene. The second electrode layer 50 may be formed of silver.

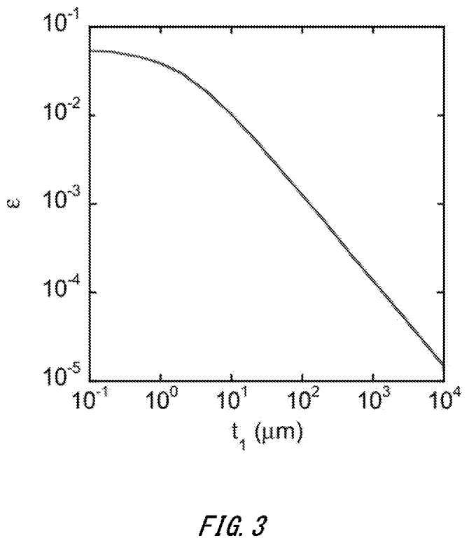

FIG. 3 shows the dependency of ε on t₁, in a case where R=1 (μm). It should be noted that t₇=t₁. Here, ε is the distortion of the surface on the first film layer 20 side, among the two surfaces of the first electrode layer 30.

As shown in FIG. 3, by setting t₁ to be greater than or equal to 10 μm, ε can be made to be approximately less than or equal to 1%. Accordingly, t₁ is preferably greater than or equal to 10 μm. Furthermore, by setting t₁ to be greater than or equal to 50 μm, a can be made to be approximately less than or equal to 0.25%. Accordingly, t₁ is more preferably greater than or equal to 50 μm. By setting t₁ to be greater than or equal to 100 μm, ε can be made to be approximately less than or equal to 0.1%. Accordingly, t₁ is even more preferably greater than or equal to 100 μm.

Here, t₁ and t₇ are preferably greater than or equal to 10 μm, more preferably greater than or equal to 50 μm, and even more preferably greater than or equal to 100 μm. However, it is acceptable for only one of t₁ and t₇ to be greater than or equal to 10 μm, only one of t₁ and t₇ to be greater than or equal to 50 μm, or only one of t₁ and t₇ to be greater than or equal to 100 μm.

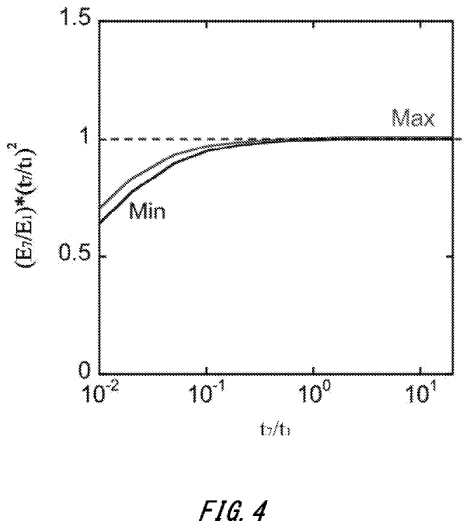

Next, as described in relation to FIGS. 4 to 9 and the like, in order to position the neutral plane between the center of the first electrode layer 30 and the center of the second electrode layer 50, t₁, E₁, t₇, and E₇ are preferably given conditions according to the two parameters of t₇/t₁ and (E₇/E₁)×(t₇/t₁)². In FIGS. 4 to 9, in a case where t₁ and E₁ are specified values, the upper limit value and lower limit value of (E₇/E₁)×(t₇/t₁)² for positioning the neutral plane between the center of the first electrode layer 30 and the center of the second electrode layer 50 are shown, with t₇/t₁ as a parameter.

FIG. 4 shows the upper limit value and lower limit value of (E₇/E₁)×(t₇/t₁)² in a case where t₁=500 (μm) and E₁=0.01 (GPa), with t₇/t₁ as a parameter.

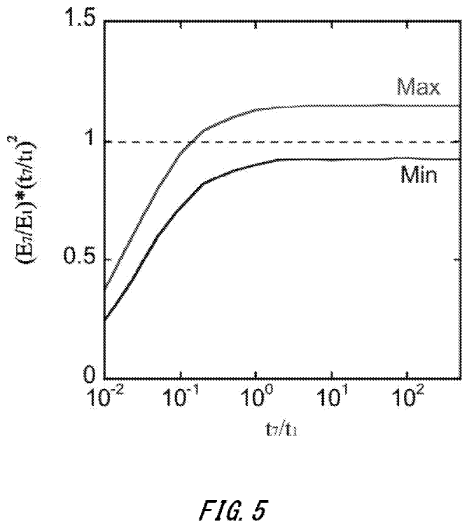

The “MAX” line in FIG. 4 indicates a case where the neutral plane matches the center of the second electrode layer 50, and the “MIN” line in FIG. 4 indicates a case where the neutral plane matches the center of the first electrode layer 30. In other words, the “MAX” line in FIG. 4 indicates the upper limit value of (E₇/E₁)×(t₇/t₁)² for positioning the neutral plane between the center of the first electrode layer 30 and the center of the second electrode layer 50. Furthermore, the “MIN” line in FIG. 4 indicates the lower limit value of (E₇/E₁)×(t₇/t₁)² for positioning the neutral plane between the center of the first electrode layer 30 and the center of the second electrode layer 50. The meanings of “MAX” and “MIN” in FIGS. 5 to 9 are the same as the meanings of “MAX” and “MIN” in FIG. 4.

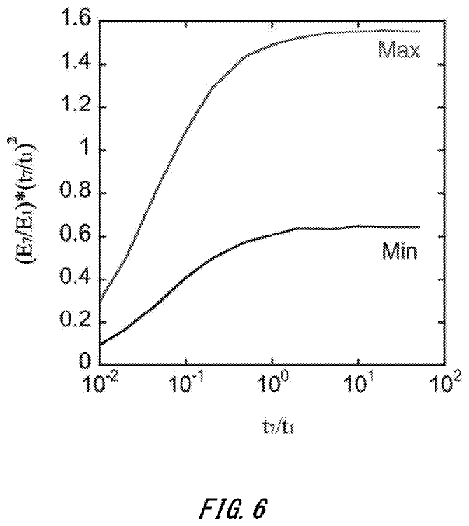

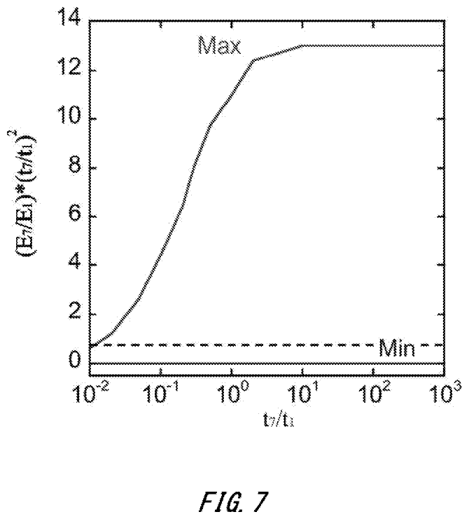

FIG. 5 shows the upper limit value and lower limit value of (E₇/E₁)×(t₇/t₁)² in a case where t₁=100 (μm) and E₁=0.01 (GPa), with t₇/t₁ as a parameter. FIG. 6 shows the upper limit value and lower limit value of (E₇/E₁)×(t₇/t₁)² in a case where t₁=50 (μm) and E₁=0.01 (GPa), with t₇/t₁ as a parameter. FIG. 7 shows the upper limit value and lower limit value of (E₇/E₁)×(t₇/t₁)² in a case where t₁=10 (μm) and E₁=0.01 (GPa), with t₇/t₁ as a parameter.

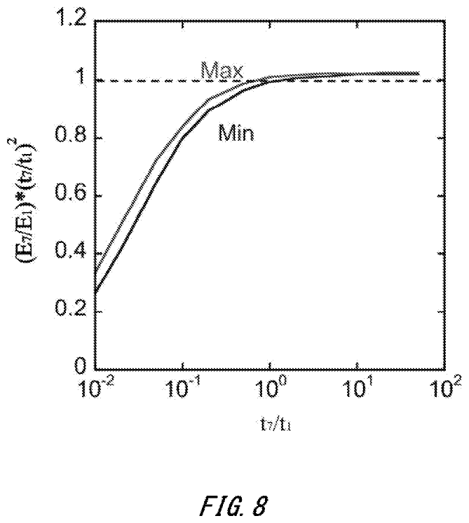

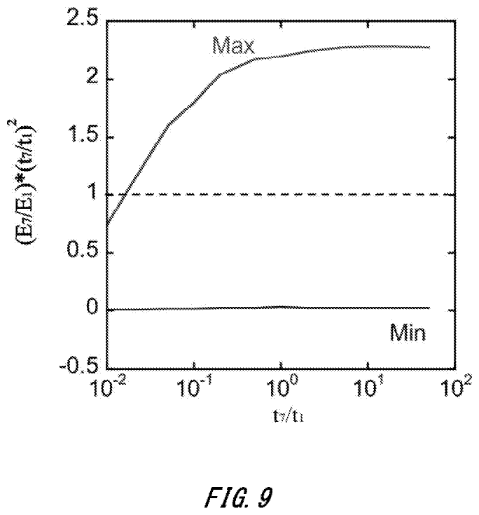

FIG. 8 shows the upper limit value and lower limit value of (E₇/E₁)×(t₇/t₁)² in a case where t₁=100 (μm) and E₁=1 (GPa), with t₇/t₁ as a parameter. FIG. 9 shows the upper limit value and lower limit value of (E₇/E₁)×(t₇/t₁)² in a case where t₁=100 (μm) and E₁=0.001 (GPa), with t₇/t₁ as a parameter.

The following describes the preferable range for t₇/t₁. From FIGS. 4 to 9, it is understood that when t₇/t₁≥0.2, the maximum limit value and minimum limit value of (E₇/E₁)×(t₇/t₁)² have a small dependency on t₇/t₁, and it is possible to generally treat these limit values as constants. Therefore, as long as t₇/t₁≥0.2, if t₁, E₁, t₇, and E₇ are determined such that (E₇/E₁)×(t₇/t₁)² is between the constant that is the upper limit value and the constant that is the lower limit value, the neutral plane can be positioned between the center of the first electrode layer 30 and the center of the second electrode layer 50. Accordingly, it is preferable that t₇/t₁≥0.2. Since the solar cell device 100 has a structure that is substantially symmetrical with respect to the photoelectric conversion layer 40, it is preferable that t₁/t₇≥0.2. Accordingly, it is preferable that 0.2≤t₇/t₁≤5.

Furthermore, from FIGS. 4 to 9, it is understood that when t₇/t₁≥0.5, the maximum limit value and minimum limit value of (E₇/E₁)×(t₇/t₁)² have an even smaller dependency on t₇/t₁. Accordingly, it is understood that when t₇/t₁≥0.5, the upper limit value and the lower limit value can be treated as constants with an even smaller error. Accordingly, it is more preferable that t₇/t₁≥0.5. When considering that the solar cell device 100 has a structure that is substantially symmetrical with respect to the photoelectric conversion layer 40, it is more preferable that 0.5 t₇/t₁≤2.

Furthermore, from FIGS. 4 to 9, it is understood that when t₇/t₁≥0.8, the maximum limit value and minimum limit value of (E₇/E₁)×(t₇/t₁)² have an especially small dependency on t₇/t₁. Accordingly, it is understood that when t₇/t₁≥0.8, the upper limit value and the lower limit value can be substantially treated as constants. Accordingly, it is even more preferable that t₇/t₁≥0.8. When considering that the solar cell device 100 has a structure that is substantially symmetrical with respect to the photoelectric conversion layer 40, it is even more preferable that 0.8≤t₇/t₁≤1.25.

As shown by the examination above concerning a preferable range for t₇/t₁, it is preferable that 0.2≤t₇/t₁≤5. It is more preferable that 0.5≤t₇/t₁≤2. It is even more preferable that 0.8≤t₇/t₁≤1.25. By setting t₁ and t₇ such that the parameter t₇/t₁ is within this preferable range, it is possible to treat the upper limit value and lower limit value of (E₇/E₁)×(t₇/t₁)² needed to position the neutral plane between the center of the first electrode layer 30 and the center of the second electrode layer 50 as constants. In the description of the present embodiment, in a case where the upper limit value and the lower limit value of (E₇/E₁)×(t₇/t₁)² can be treated as constants, these values may be referred to respectively as an “upper limit constant value” and a “lower limit constant value”.

The following describes a desirable range for (E₇/E₁)×(t₇/t₁)². As described above, in order to make ε less than or equal to approximately 1% when the curvature radius is R=1 (μm), it is preferable that t₁≥10 (μm). With reference to FIG. 7 in the case where t₁=10 (μm), it is understood that if t₁, E₁, t₇, and E₇ are set such that 0.1≤(E₇/E₁)×(t₇/t₁)²≤10, the neutral plane can be positioned between the center of the first electrode layer 30 and the center of the second electrode layer 50. Furthermore, with reference to FIGS. 4, 5, 6, 8, and 9, the range between the upper limit constant value and the lower limit constant value of (E₇/E₁)×(t₇/t₁)² is included in the range that is greater than or equal to 0.1 and less than or equal to 10. Accordingly, it is preferable that at least 0.1≤(E₇/E₁)×(t₇/t₁)²≤10.

Furthermore, it is more preferable that 0.5≤(E₇/E₁)×(t₇/t₁)²≤2. As shown in the embodiment example of FIG. 9, in a case where the first elastic layer 10 and the second elastic layer 70 are formed of a soft material, the range of 0.5≤(E₇/E₁)×(t₇/t₁)²≤2 is within the range between the lower limit constant value and the upper limit constant value of (E₇/E₁)×(t₇/t₁)². In other words, if 0.5≤(E₇/E₁)×(t₇/t₁)²≤2, when the first elastic layer 10 and the second elastic layer 70 are formed of a soft material, it is possible to position the neutral plane between the center of the first electrode layer 30 and the center of the second electrode layer 50. Accordingly, if 0.5≤(E₇/E₁)×(t₇/t₁)²≤2, by using soft materials for the first elastic layer 10 and the second elastic layer 70, it is possible to prevent a loss of the ability to track the curved surface, and also to make it difficult for a difference to occur between the distortion applied to the first electrode layer 30 and the distortion applied to the second electrode layer 50 when the solar cell device 100 is deformed.

Furthermore, it is even more preferable that 0.8≤(E₇/E₁)×(t₇/t₁)²≤1.25. By satisfying this condition, the selection options for t₁, E₁, t₇, and E₇ can be expanded.

As shown by the examination above concerning a preferable range for (E₇/E₁)×(t₇/t₁)², it is preferable that 0.1≤(E₇/E₁)×(t₇/t₁)²≤10. It is more preferable that 0.5≤(E₇/E₁)×(t₇/t₁)²≤2. It is even more preferable that 0.8≤(E₇/E₁)×(t₇/t₁)²≤1.25. By causing the parameter (E₇/E₁)×(t₇/t₁)² to be within the preferable range described above, it becomes easy to position the neutral plane between the center of the first electrode layer 30 and the center of the second electrode layer 50, and it is also possible to make it more difficult for a difference to occur between the distortion applied to the first electrode layer 30 and the distortion applied to the second electrode layer 50.

The above describes conditions relating to the parameters t₁ and E₁ of the first elastic layer 10 and to the parameters t₇ and E₇ of the second elastic layer 70. The thickness t₂ of the first film layer 20 is preferably such that t₂≤30 μm, in consideration the tracking ability and the ease of attachment with respect to an uneven surface. In order to increase the tracking ability and ease of attachment, it is more preferable that t₂≤10 μm. In order to further increase the tracking ability and ease of attachment, it is even more preferable that t₂≤2 μm.

In the solar cell device 100, the material forming the first elastic layer 10 is not limited to a rubber or polymer material. The material forming the first elastic layer 10 may be glass. Similarly, the material forming the second elastic layer 70 is not limited to a rubber or polymer material. The material forming the second elastic layer 70 may be glass.

In the solar cell device 100, the second base material layer 120 includes the second film layer 60 and the second elastic layer 70. However, the second base material layer 120 does not need to include the second film layer 60. The second base material layer 120 may include only the first elastic layer 10.

In the solar cell device 100, the first base material layer 110 includes the first elastic layer 10 and the first film layer 20, and the second base material layer 120 includes the second film layer 60 and the second elastic layer 70. However, at least one of the first base material layer 110 and the second base material layer 120 may be a single layer formed by a single material.

In the above description, the solar cell device 100 is provided as an example of a semiconductor device. However, the semiconductor device is not limited to a solar cell device. The semiconductor device may be a light emitting device. For example, a light emitting layer may be used as the semiconductor layer, instead of the photoelectric conversion layer 40 described above. The light emitting layer may include an organic light emitting diode, a light emitting polymer, or the like. The semiconductor layer may include both the photoelectric conversion layer and the light emitting layer. The semiconductor layer may be a current light emitting layer, an electrical field light emitting layer, an organic transistor layer, or a combination of these. The semiconductor layer is not limited to a photoelectric conversion layer or a light emitting layer. The semiconductor layer may include organic semiconductors having various functions differing from a photoelectric conversion function and a light emission function. The semiconductor layer may be formed using a semiconductor material such as an organic material, an oxide material, or amorphous silicon. An organic semiconductor material can be favorably used as the material for forming the semiconductor layer due to having good flexibility and applicability, or a compound semiconductor material such as CIGS or CIS, a perovskite compound material, or the like can be used according to the objective. The semiconductor device may be a field effect transistor, an integrated circuit, or the like. The semiconductor device may include various sensors and corresponding detection circuits, or a secondary battery. The semiconductor device may be a power generation device, an illumination device, a display device, electronic paper, a power storage device, a sheet-shaped sensor device, or a combination of these devices.

While the embodiments of the present invention have been described, the technical scope of the invention is not limited to the above described embodiments. It is apparent to persons skilled in the art that various alterations and improvements can be added to the above-described embodiments. It is also apparent from the scope of the claims that the embodiments added with such alterations or improvements can be included in the technical scope of the invention.

The operations, procedures, steps, and stages of each process performed by an apparatus, system, program, and method shown in the claims, embodiments, or diagrams can be performed in any order as long as the order is not indicated by “prior to,” “before,” or the like and as long as the output from a previous process is not used in a later process. Even if the process flow is described using phrases such as “first” or “next” in the claims, embodiments, or diagrams, it does not necessarily mean that the process must be performed in this order.

### LIST OF REFERENCE NUMERALS

100: solar cell device
10: first elastic layer
20: first film layer
30: first electrode layer
40: photoelectric conversion layer
50: second electrode layer
60: second film layer
70: second elastic layer
101: first surface
102: second surface
110: first base material layer
120: second base material layer

What is claimed is:

1. A semiconductor device comprising:
a first base material layer that is elastic;
a first electrode layer provided on the first base material layer;
a semiconductor layer provided on the first electrode layer;
a second electrode layer provided on the semiconductor layer; and
a second base material layer that is elastic and provided on the second electrode layer, wherein
a plane whose distance b from one surface of the semiconductor device in a thickness direction of the semiconductor device is expressed by Expression 1 is positioned between a center of the first electrode layer and a center of the second electrode layer in the thickness direction,
Expression 1 is
$$b = {\sum }_{i = 1}^{n} {E}_{i} {t}_{i} [ {\sum }_{j = 1}^{i} {t}_{j} - \frac{{t}_{i}}{2} ] / {\sum }_{i = 1}^{n} {E}_{i} {t}_{i}$$
n indicates the number of layers in the semiconductor device,
Eᵢ indicates an elastic modulus of an i-th layer from the one surface of the semiconductor device, among the layers of the semiconductor device, and
tᵢ and tⱼ respectively indicate thicknesses of the i-th layer and a j-th layer.

2. The semiconductor device according to claim 1, wherein
the first base material layer includes a first elastic layer and a first film layer provided on the first elastic layer,
the first electrode layer is provided on the first film layer, and
the second base material layer includes a second film layer provided on the second electrode layer and a second elastic layer provided on the second film layer.

3. The semiconductor device according to claim 2, wherein
with E₁ representing the elastic modulus of the first elastic layer, t₁ representing the thickness of the first elastic layer, E₇ representing the elastic modulus of the second elastic layer, and t₇ representing the thickness of the second elastic layer, the expressions 0.2≤t₇/t₁≤5 and 0.1≤(E₇/E₁)×(t₇/t₁)²≤10 are satisfied.

4. The semiconductor device according to claim 3, wherein
the expression 0.5≤(E₇/E₁)×(t₇/t₁)²≤2 is satisfied.

5. The semiconductor device according to claim 3, wherein
the expression 0.8≤(E₇/E₁)×(t₇/t₁)²≤1.25 is satisfied.

6. The semiconductor device according to claim 3, wherein
the expression 0.5≤t₇/t₁≤2 is satisfied.

7. The semiconductor device according to claim 3, wherein
the expression 0.8≤t₇/t₁≤1.25 is satisfied.

8. The semiconductor device according to claim 2, wherein
with t₁ representing the thickness of the first elastic layer and t₇ representing the thickness of the second elastic layer, at least one of t₁ and t₇ is greater than or equal to 10 μm.

9. The semiconductor device according to claim 2, wherein
with t₁ representing the thickness of the first elastic layer and t₇ representing the thickness of the second elastic layer, at least one of t₁ and t₇ is greater than or equal to 50 μm.

10. The semiconductor device according to claim 2, wherein
with t₁ representing the thickness of the first elastic layer and t₇ representing the thickness of the second elastic layer, at least one of t₁ and t₇ is greater than or equal to 100 μm.

11. The semiconductor device according to claim 1, wherein
the first electrode layer is a transparent electrode layer, and
the first base material layer is transparent.

12. The semiconductor device according to claim 11, wherein
the semiconductor layer is a photoelectric conversion layer.
